(19) United States
(12) Patent Application Publication
(10) Pub. No.: US 2016/0218739 A1
(43) Pub. Date: Jul. 28, 2016

(54) DATA ACCESS METHODS AND DATA ACCESS DEVICES UTILIZING THE SAME

(71) Applicant: MEDIATEK INC., Hsin-Chu (TW)

(72) Inventor: Kun-Bin LEE, Taipei City (TW)

(21) Appl. No.: 14/916,175

(22) PCT Filed: Feb. 17, 2015
(86) PCT No.: PCT/CN2015/073234

§ 371 Date: Mar. 2, 2016

Related U.S. Application Data
(60) Provisional application No. 61/940,695, filed on Feb. 17, 2014.

(51) Int. Cl. H03M 7/30; G11C 11/406; G11C 7/10

(52) U.S. Cl. CPC H03M 7/3066; G11C 7/1072; G11C 11/40622

(57) ABSTRACT

Data access methods are provided. The method includes: acquiring a data array which is partitioned into a plurality of regions; and for each of the regions, writing a plurality of data units representing the region into a segment of a memory device and recording both of length information and data arrangement information corresponding to the region, wherein a burst length of a burst access performed on the data units representing the region is defined according to the length information.

### CROSS REFERENCE TO RELATED APPLICATIONS

This application claims priority of U.S. Patent Application No. 61/940,695, filed on Feb. 17, 2014, the entirety of which is incorporated by reference herein.

### FIELD OF THE INVENTION

The present invention relates to data storage, and in particular, to data access methods and data access devices utilizing the same.

### BACKGROUND AND RELATED ART

Synchronous dynamic random access memory (SDRAM) is dynamic random access memory (DRAM) that is synchronized with a system bus of a computer system. There are several types or families of SDRAM available in the market, including Low Power DDR (LPDDR) (i.e., Mobile DDR) and double data rate synchronous dynamic random access memory (DDR SDRAM). The different types of SDRAM differ from each other in certain respects (e.g., speed, power consumption, and price, among others).

In data access such as image access or a program access, a data array is often divided into a plurality of data blocks for data access. Data sizes of the data blocks are often different. Further, each data block could be accessed from the SDRAM in pre-determined or order or a random order. In some applications, a data block could be accessed not only once but multiple times. In some applications, a data block could be written by a first processing engine in a first preferred access behavior while be read by a second processing engine in a second preferred access behavior. Examples of access behaviors are block-based access for video codec and GPU processing. Examples of access behaviors are raster scan access for display processing. Therefore, data access methods for accessing data from the SDRAM are required.

### BRIEF SUMMARY OF THE INVENTION

A detailed description is given in the following embodiments with reference to the accompanying drawings.

An embodiment of a data access method is described, comprising: acquiring a data array which is partitioned into a plurality of regions; and for each of the regions, writing a plurality of data units representing the region into a segment of a memory device and recording both of length information and data arrangement information corresponding to the region, wherein a burst length of a burst access performed on the data units representing the region is defined according to the length information.

Another embodiment of a data access method is provided, comprising: acquiring a data array which is partitioned into a plurality of regions; and for each of the regions, writing a plurality of data units representing the region into a segment of a memory device, wherein a start address of a write transaction for at least one of the data units is generated based on length information of the corresponding data unit.

Another embodiment of a method of accessing data in a data processing system with a memory device is disclosed, comprising: performing an access operation on the memory device by accessing, according to a first memory footprint, a plurality of data units representing a plurality of regions of a first data array; performing the access operation on the memory device by accessing, according to a second memory footprint, a plurality of data units representing a plurality of regions of a second data array; and processing length information of each data unit corresponding to the first data array and each data unit corresponding to the second data array.

### BRIEF DESCRIPTION OF THE DRAWINGS

The present invention can be more fully understood by reading the subsequent detailed description and examples with references made to the accompanying drawings, wherein:

FIG. 1 is a block diagram of a data access system 1 according to an embodiment of the invention;

FIG. 2 is a memory layout diagram of a data access device;

FIGS. 3A, 3B and 3C illustrate layouts of different data types in any region of a data array according to several embodiments of the invention;

FIGS. 4A and 4B show image objects drawn on an image array that is partitioned by 2 data types according to an embodiment of the invention;

FIG. 5 is a memory layout diagram of a data access scheme 5 according to an embodiment of the invention;

FIGS. 6A and 6B are memory layout diagrams of a data access scheme 6 according to another embodiment of the invention;

FIGS. 7A and 7B are memory layout diagrams of data access schemes 7A and 7B according to another embodiment of the invention;

FIGS. 8A, 8B and 8C are memory layout diagrams of a data access scheme 8 according to another embodiment of the invention;

FIG. 9 is a memory layout diagram of a memory segment which illustrates a data access scheme 9 according to an embodiment of the invention;

FIG. 10 is a memory layout diagram of a memory segment which illustrates a data access scheme 10 according to another embodiment of the invention;

FIG. 11 is a memory layout diagram of a memory segment which illustrates a data access scheme 11 according to another embodiment of the invention;

FIG. 12 is a memory layout diagram of a memory segment which illustrates a data access scheme 12 according to another embodiment of the invention;

FIG. 13 is a flowchart of a data access method 13 according to an embodiment of the invention;

FIG. 14 is a flowchart of an address generation method 14 according to an embodiment of the invention;

FIG. 15 is a flowchart of a data accessing method 15 according to another embodiment of the invention;

FIG. 16 is a block diagram of an address generation circuit 16 of a write circuit of the data access device according to an embodiment of the invention;

FIGS. 17A and 17B are block diagrams of length caches 17A and 17B of a write circuit of the data access device according to embodiments of the invention;

FIG. 18 is a block diagram of an address generation circuit 18 of a read circuit of the data access device according to an embodiment of the invention;

FIG. 19 is a block diagram of length cache 19 of a read circuit of the data access device according to embodiments of the invention;

FIG. 20 are a data array of uncompressed data, compressed data, and length information thereof respectively;

FIG. 21 is a memory layout diagram 21 which illustrates a data access scheme according to an embodiment of the invention; and

FIG. 22 is a memory layout diagram 22 which illustrates a data access scheme according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

As used herein, the term “chip” may also be referred to as an integrated circuit operating in a personal computer, a small computer such as a mobile phone, MP3 player, and handheld game console, or a mobile computer such as a laptop computer, or an embedded computer such as a factory controller, motor vehicle controller, and toy. For simplicity and consistency, we will use the term computer throughout the disclosure.

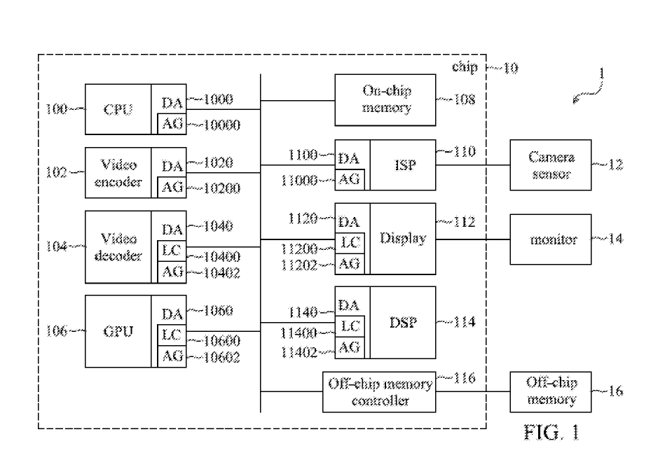

FIG. 1 is a block diagram of a data access system 1 according to an embodiment of the invention. The data access system 1 may be contained in a computer, a gaming system, a smartphone, a tablet, a TV system, a multimedia player system, or an interactive video system. The data access system 1 comprises a chip 10, a camera sensor 12, a monitor device 14 such as a Liquid-Crystal Display (LCD) monitor, and an off-chip memory 16 such as a hard disk drive. The chip 10 is connected to the camera sensor 12 to process the image data, connected to the monitor device 14 to display visual images, and connected to the Off-chip memory 16 to access external data. It would be appreciated that the bus connection in FIG. 1 merely depicts one possible implementation, and is not intended to serve as a limit to the invention.

In this embodiment, the chip 10 comprises a plurality of data access devices, such as a Central Processing Unit (CPU) 100, a video encoder 102, a video decoder 104, a Graphics Processing Unit (GPU) 106, an Image Signal Processor (ISP) 110, a display controller 112, and a Digital Signal Processor (DSP) 114. Further, the chip 10 comprises an on-chip memory 108 and an off-chip memory controller 116 which manages operations of the off-chip memory 16. However, other circuits and components may be present in the chip 10. The data access devices may access data to and from the on-chip memory 108 and the off-chip memory 16 according to the data access methods disclosed in the present application.

As shown in FIG. 1, each of the data access devices comprises a data agent (such as the DA 1000, the DA 1020, the DA 1040, the DA 1060, the DA 1100, the DA 1120, and the DA 1140) for providing Direct Memory Access (DMA). In some embodiment, the data agent may or may not include the function of data compression and/or decompression. Besides, each data access device comprises an address generation circuit (such as the AG 10000, the AG 10200, the AG 10402, the AG 10602, the AG 11000, the AG 11202, and the AG 11402) for generating address data according to the data access behavior. Some of the data access devices comprise a length cache (such as the LC 10400, the LC 10600, the LC 11200, and the LC 11400), wherein the length cache may be a cache memory or a length buffer. For example, the display controller 112 accesses image data in a very regular and predictable manner, thus the LC 11200 can be a length buffer. In another example, the video decoder 104 and GPU 106 access image data in an irregular and unpredictable manner, thus LC 10400 and the LC 10600 would be the cache memory.

The CPU 100 controls operations of the all components in the chip 10. The on-chip memory 108 temporarily stores a portion of an Operating System (OS) program or an application software program (hereinafter referred to as an application) to be executed by the CPU 100. In addition, the on-chip memory 108 stores various data required by the CPU 100 and/or other components in chip 10. The on-chip memory 108 and the off-chip memory 16 may be a Dynamic Random-Access Memory (DRAM), Synchronous Dynamic Random-Access Memory (SDRAM), a Double Data Rate (DDR) SDRAM such as DDR1, DDR2, DDR3, DDR4, Low Power DDR (DDR), other types of SDRAM, or Synchronous Graphics RAM (SGRAM).

In some embodiments, each read port (not shown) and/or write port (not shown) of each data access device includes a data agent. In other embodiments where the data throughput is low, two or more of the read port (not shown) and/or write port (not shown) may share the same data agent or a part of the data agent. For example, a read port and a write port of a data access device may share a common address generation circuit but use separate length caches.

The accessed data of the on-chip memory 108 and the off-chip memory 16 may have a fixed length or a variable length. For example, in order to reduce the data bandwidth of transmissions, the data are compressed prior to be written into the off-chip memory 16, resulting in the variable data length thereof.

Data access performance of the off-chip memory 16 is determined by the number of transactions required for accessing the data, the burst length of each transaction, and the storage locations of the accessed data in the off-chip memory 16. In general, the data access performance increases as the number of total data transactions for one burst transfer decreases. The burst length must be a power of two, such as 1, 2, 4, 8, 16 words, or other predetermined lengths of data words. For a burst length of 2 data words, the requested word is accessed first, following by accessing the second word in the aligned data block. When transferring large amounts of data, the number of total transactions can be reduced by increasing the burst length and allowing single transaction to span more than one data words. Also, when a burst transfer can be completed in a single transaction instead of two or more transactions, the data access performance will also increase.

Further, since the data are transmitted by burst transfers and each data burst always accesses an addressed-aligned block of a burst length of consecutive words beginning on a multiple of the burst lengths, the data access performance is increased when the data burst accesses from the start of the addressed-aligned block of the off-chip memory 16. For example, for a data block of 64-byte, if a start address of a data burst is 64-byte aligned, the data transaction will involve the entire 64-bytes block, whereas if the start address of the data burst is not 64-byte aligned, then the off-chip memory 16 will require extended time to provide the requested data. As a consequence, the access performance is increased when the data burst starts from the aligned block.

When writing data into the off-chip memory 16, the data access device can arrange the data into the off-chip memory 16 according to a predefined memory footprint while keeping data arrangement information, such that later, the data can be read out from the off-chip memory 16 according to the predefined memory footprint and/or the data arrangement information, resulting in a reduced number of total data transactions and a decreased period of access time, thereby increasing memory utilization and data access performance.

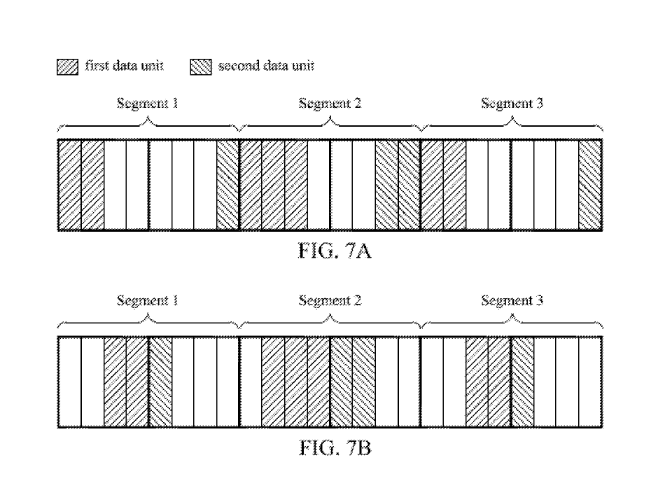

The data arrangement information may indicate a writing order of the data being written in a predefined segment of the off-chip memory 16, or the memory footprint being adopted by the data, allowing the data access device to write data in the off-chip memory 16 in a random order, while being able to identify the data later. The memory footprint of the off-chip memory 16 represents start positions and writing direction of data of the region, as well as defining an area in the memory segment where the data of the region are to be written, allowing the data access device to access data from the predefined memory segment multiple times in a random order, wherein each data may have different length. Data access methods adopted by the data access devices using the data arrangement information for accessing data from the off-chip memory 16 are detailed in FIGS. 5, 6A, 6B and 15. Data access methods adopted by the data access devices using the predetermined memory layout for accessing data from the off-chip memory 16 are detailed in FIGS. 7A, 7B, 8A, 8B, 8C, 9, 10, 11, 12, 13, 14, and 15.

Specifically, the data access methods in the embodiments address a data array which can be acquired and partitioned into a plurality of regions, and correspondingly, a plurality of memory segments are allocated in the off-chip memory 16, with each memory segment being allocated for a corresponding region. For each region, the data access device can write data units representing the region into a corresponding segment of the off-chip memory 16, and record length information and data arrangement information corresponding to the region. A burst length of a burst access performed on the data representing the region is defined according to the length information. In some embodiments, the plurality of regions are substantially equal in size, and the plurality of segments are also substantially equal in size. In other embodiments, the plurality of regions are different in sizes, and the plurality of segments are different in sizes. The data arrangement information indicates a write order and/or a memory footprint of the data in the same region of the data array.

Although the data access methods are applicable to the off-chip memory 16 in the embodiments of the present application, the applications are not limited to the off-chip memory 16. Rather, the data access methods may also be applicable to the on-chip memory 108, particularly when the on-chip memory 108 is an embedded DRAM or other types of DRAM devices.

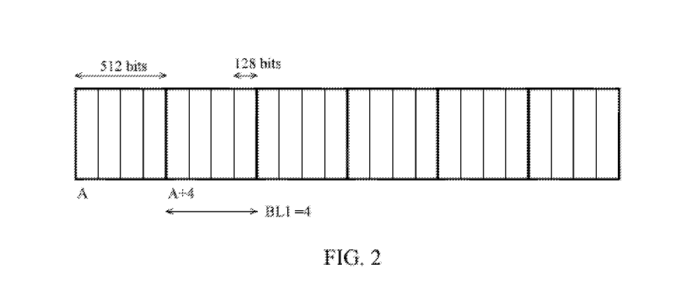

FIG. 2 is a memory layout diagram of a memory device according to embodiments of the invention. The memory device may be the off-chip memory 16 in FIG. 1, containing a plurality of memory words with a word size of 128 bits, or 16 bytes, where every 8 words are grouped into a memory segment for holding the region data. For example, the memory words with addresses from A to (A+7) form a memory segment for accessing the data units. In order to provide the increased data access performance, the data access device is configured to access the data units from the base address A, rather than a non-base address such as (A+1) of each memory segment.

To be specific, the data access performance of the off-chip memory 16 is determined by the number of transactions required for accessing the data units, the burst length of each transaction, and the storage locations of the accessed data units in the off-chip memory 16. For a burst length of 2 data words, the requested word is accessed first, following by accessing the second word in the aligned data block. When transferring large amounts of data, the number of total transactions can be reduced by increasing the burst length and allowing single transaction to span more than one data words. Also, when a data transfer can be completed in a single transaction instead of two or more transactions, the data access performance will also increase.

Further, since the data units are transmitted by burst transfers and each data burst always accesses an addressed-aligned block of a burst length of consecutive words beginning on a multiple of the burst lengths, the data access performance is increased when the data burst accesses from the start of the addressed-aligned block of the off-chip memory 16. For example, for a data block of 64-byte, if a start address of a data burst is 64-byte aligned, the data transaction will involve the entire 64-bytes block, whereas if the start address of the data burst is not 64-byte aligned, then the off-chip memory 16 will require extended time to provide the requested data. As a consequence, the access performance is increased when the data burst starts from the aligned block.

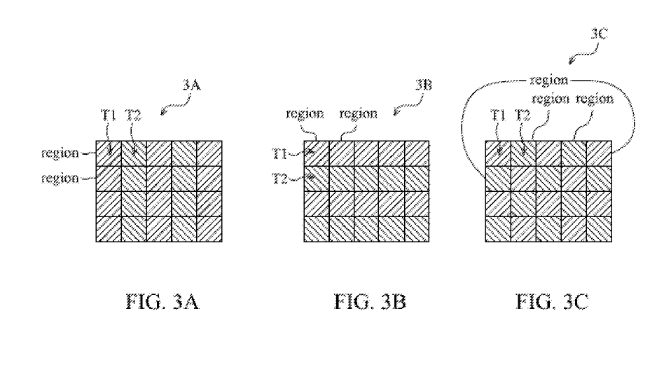

Referring to FIGS. 3A, 3B and 3C, which illustrate layouts of two different data units T1 and T2 in the plurality of regions of an array of data (hereinafter, referred to as “data array”) according to several embodiments of the invention. Prior to access the data array, the data array is partitioned into regions as depicted in FIG. 3A, 3B or 3C. Each region includes the data units to be accessed in the corresponding memory segment of the off-chip memory 16. As a result, the data access device allocates a size of the memory segment to be the same or exceed that of the corresponding region. In some embodiments, a data size of a region, and data sizes of the data units T1 and T2 in the region are adaptable by the data access device. For example, the size of a data unit may ranges from 1 to 512 bits. Assuming that each memory entry in a memory segment has 128 bits, then a data unit with 130 bits may occupy two memory entries.

In FIG. 3A, the data array 3A is divided into a plurality of regions, wherein each region is further vertically divided into two equal sub-regions, with the left sub-region containing the data unit T1 and the right sub-region containing data unit T2. The data units T1 and T2 in the same region will be accessed in the corresponding memory segment in one or more burst transfers. For example, each region may contain four-word uncompressed data unit T1 and four-word uncompressed data unit T2, which can be accessed from the memory segment addressed from Address A to Address (A+7) in FIG. 2. In some embodiments, the data units are compressed before being written into the corresponding memory segment. As a consequence, the data units may have fixed or variable data lengths.

In FIG. 3B, the data array 3B is divided into a plurality of regions, wherein each region is further horizontally divided into two equal sub-regions, with the top sub-region containing the data unit T1 and the bottom sub-region containing data unit T2. The data units T1 and T2 in the same region will be accessed from the same memory segment in one or more burst transfers.

In FIG. 3C, the 2-dimensional data array 3C is flatten into a 1-dimensional array and divided into a plurality of equal-sized sub-regions, wherein each pair of adjacent sub-regions are further grouped into a region. For each region, the left sub-region contains the data unit T1 and the right sub-region contains data unit T2. The data units T1 and T2 in the same region will be accessed in the same memory segment in one or more burst transfer. Although the embodiments in FIGS. 3A, 3B, and 3C show that a region contains only two data units, those skilled in the art would recognize that two or more data units may be used to identify two or more sub-regions in each region of the data array.

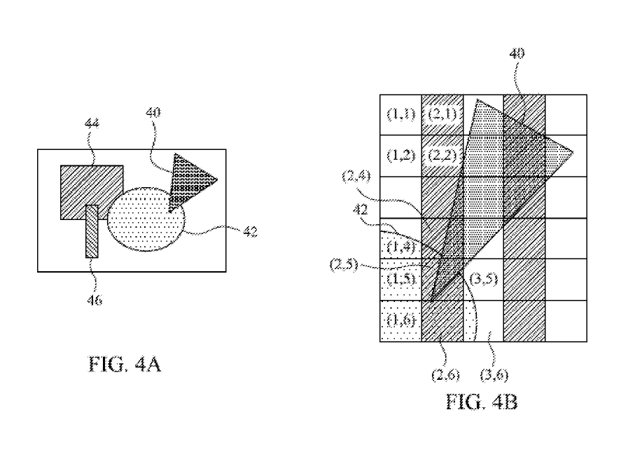

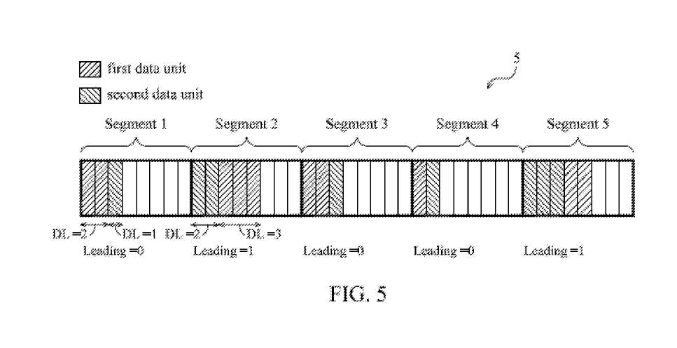

In certain embodiments, the data access method can be adopted by the GPU 106, in which regions of an image data array may be repeatedly read from, modified, and written back to the off-chip memory 16 in a random order. As shown in FIG. 4A, four objects are drawn on a display. Specifically, a square 44, a rectangular 46, a circle 42, and a triangle 40 are drawn in sequence. The GPU 106 may need to access the data units of a region several times to update the image data array. For example, the GPU 106 accesses the regions which contains overlapped objects or parts of objects, such as the regions including parts of the circle 42 and the triangle 40, multiple times, in response to modification made by the overlapping object(s), i.e., the addition of the triangle 40.

Taking FIG. 4B as an example, which illustrates the triangle 40 and the circle 42 are partitioned by 2 data units according to an embodiment of the invention. Parts of the circle 42 are drawn on the sub-regions (1, 4), (2, 4), (1, 5), (2, 5), (3, 5), (1, 6), (2, 6), (3, 6) firstly, then parts of the triangle 40 are drawn on the sub-regions (2, 4), (2, 5), (3, 5). The GPU 106 writes data units representing the circle 42 on the sub-regions (1, 4), (2, 4), (1, 5), (2, 5), (3, 5), (1, 6), (2, 6), (3, 6) into the corresponding segments of the off-chip memory 16, then reads the data units of the sub-regions (2, 4), (2, 5), (3, 5) from the corresponding segments of the off-chip memory 16, modifies the read sub-regions, and writes back to the corresponding segments of the off-chip memory 16. In other words, the sub-regions (2, 4), (2, 5), (3, 5) are twice modified and written into the off-chip memory 16 by the GPU 106. As a consequence, the values and sizes of the data units of the sub-regions (2, 4), (2, 5), (3, 5) are most likely changed. In another embodiment, a cache is integrated with GPU 106. In this embodiment, sub-regions (2, 4), (2, 5), (3, 5) may be updated twice for the circle 42 and the triangle 40 in the cache instead of in the off-chip memory 16. Sub-regions (2, 4), (2, 5), (3, 5) in the cache then be replaced and written to the off-chip memory 16 due to cache replacement mechanism or be flushed and written to the off-chip memory 16 due by a demand from an application software. The data access schemes disclosed in the following paragraphs can be adopted to deal with the multiple-accessed, random-accessed, and variable-length data transaction example described in FIGS. 4A and 4B.

FIG. 5 is a memory layout diagram of a data access scheme 5 according to an embodiment of the invention. The data access scheme 5 allows random data access and variable data length data storage by employing data arrangement information to identify a write order of data units stored in memory segments of the off-chip memory 16.

The memory layout diagram in FIG. 5 depicts 5 memory segments of the off-chip memory 16, each memory segment is 8 words in length and allocated for 2 data units in a corresponding region of the data array. The 2 data units are respectively represented by slash and backslash shaded area. Prior to access the off-chip memory 16, the data access device has already allocated the 5 memory segments of the off-chip memory 16 for 5 regions of the data array. Since the data access scheme 5 can be adopted for random as well as sequential data access, it can allow a first or a second data unit to be written into the memory segment in the first place. As a result, the data access scheme 5 introduces the data arrangement information to indicate whether data units have been written into the memory segment and which data unit is being written into the memory segment firstly. In some embodiments, when the first data unit is written into the corresponding memory segment in the first place, the data arrangement information indicates a parameter Leading=0, whereas when the second data unit is written into the corresponding memory segment in the first place, the data arrangement information indicates a parameter Leading=1. In another embodiment, a cache or a data output buffer can be used. A first data unit with data length of two (DL=2) is written into segment 1 first and a second data unit with data length of one (DL=1) is written into segment 1 later. These two data units are written into a cache or data output buffer with data arrangement information Leading=0. These two data units in the cache or data output buffer then are written to the off-chip memory 16 due to cache replacement mechanism or output data buffer control mechanism. By this method, the data units can be written to or read from the off-chip memory 16 with longer burst length. Therefore, the memory access performance is enhanced.

For the first region, the data access device records the first data unit then subsequently the second data unit into the first memory segment. Before writing the first data unit into the first memory segment, the data access device can determine that no data unit has been written in the first memory segment by absence of the data arrangement information or by invalid data arrangement information. When the data access device writes the first data unit of the first region into the first memory segment, it also records the data arrangement information Leading=0 which indicates that the first data unit has been written firstly into the first memory segment, along with length information which indicates the first data unit has a data length of 2 words. The data access device may record the data arrangement information and the length information in local registers, buffers, caches, or memory devices in form of a finite state machine, counter, or flag. Before the data access device writes the second data unit of the first region into the first memory segment, it can acquire the data arrangement information from the local registers, buffers, caches, or memory devices, and determine that the first data unit has already been present. In response, the data access device writes the second data unit of the first region into the empty space of the first memory segment that is successive to the first data unit, and stores length information which indicates the second data unit has a data length of 1 word. In some embodiments, only the total data length of the first and second data units is stored. For example, data units are compressed and then stored into the off-chip memory 16. When read compressed data units from the off-chip memory 16, only total length of data units is required for minimizing access burst length. Decompression is then performed to extract data units. The order of data units are is determined by the data arrangement information. By the similar operations, the data access device writes the first and second data units into each of the remaining four regions of the data array. As shown in FIG. 5, the data arrangement information Leading of each of the remaining four regions would be 1, 0, 0, and 1.

In some embodiments, instead of utilizing the data arrangement information, the data access device may use the length information which indicates a data length of a particular data unit, and if the data lengths of both data units are zero, or unavailable, then the data access device may determine that no data unit has been written into the memory segment yet. In other embodiments, the data access device records a first data length of the data unit which is firstly written into the memory segment, and records a total length of the first and second data units when the other data unit is written into the memory segment.

The data access scheme 5 assigns a dedicated memory segment for each region of the data array, and employs the data arrangement information to identify a write order of data units or memory layout of data units stored in memory segments of the off-chip memory 16, thereby allowing random access of data units of a region, especially for variable data length of data units.

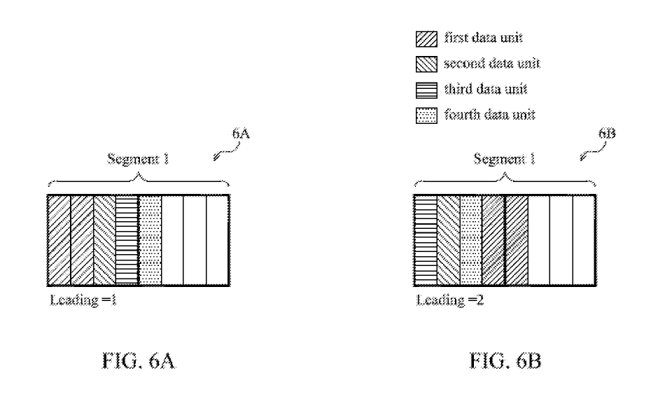

FIGS. 6A and 6B are memory layout diagrams of a data access scheme 6 according to another embodiment of the invention, incorporating the data access system 1 in FIG. 1. The data access scheme 6 writes four data units of a region of a data array into a memory segment 1 by utilizing data arrangement information, and is adopted for data transactions of sequential or random data access and variable data lengths.

In some embodiments, the data arrangement information represents the arrangement layout for data units of a particular region. For example, the embodiment in FIG. 6A shows the four data units being laid out in the order of: a first data unit having a data length of 2 words, a second data unit having a data length of 1 word, a third data unit having a data length of 1 word, and a fourth data unit having a data length of 1 word. The data arrangement information Leading is set to 1 to indicate this arrangement layout case of the memory segment 1. In another example as illustrated by the embodiment in FIG. 6B, the four data units being laid out in the order of: the third data unit having a data length of 1 word, the second data unit having a data length of 1 word, the fourth data unit having a data length of 1 word, and the first data unit having a data length of 2 words. The data arrangement information Leading is set to 2 to indicate this arrangement layout case of the memory segment 1. Later, in a read operation, the four data units can be read out in a single data transaction with a burst length equal to a sum of all data lengths. Alternatively, when the total data length of the four data units is longer than a specific threshold, the four data units may have to be read out by more than one burst accesses. However, the burst accesses still could be done in a single transaction. For example, in a single transaction, there could be three burst accesses with burst length of 8, 8, and 3 respectively.

In other embodiments, the data arrangement information represents a memory footprint of the four data units in the memory segment 1 in form of start positions. In write operations, the data access device stores the data arrangement information representing the start position of each data unit written into the memory segment 1, as well as the length information corresponding to the stored data unit. For example, the total data length of stored data units in segment 1 would be stored along with the start position of each data unit. Alternatively, the data length of each stored data unit would be stored along with the start position of each data unit. Later, in a read operation, the four data units can be read out in a single data transaction with a burst length equal to all data lengths added together, or in two or more data transactions according to the start positions and the data lengths. Alternatively, when the total data length of the stored data units is too long, the stored data units would be read out by more than one burst accesses. However, the burst accesses would be done in a single transaction.

For example, the embodiment in FIG. 6A shows that the first data unit starts at position word0 and has a data length of 2 words, the second data unit starts at position word2 and has a data length of 1 word, the third data unit starts at position word3 and has a data length of 1 word, and the fourth data unit starts at position word4 and has a data length of 1 word. The data arrangement information may further contain parameter Leading as being 1, indicating the first data unit is being stored at the start position of the memory segment 1. Accordingly, the memory footprint may include start positions information of all stored data units. Alternatively, start positions information of stored data units may be separately stored in local registers, buffers, caches, or memory devices (e.g., the off-chip memory 16). In the latter case the data arrangement information can be obtained before access of data units stored in the off-chip memory 16. In another example as illustrated by the embodiment in FIG. 6B shows that the first data unit starts at position word3 and has a data length of 2 words, the second data unit starts at position word1 and has a data length of 1 word, the third data unit starts at position word0 and has a data length of 1 word, and the fourth data unit starts at position word2 and has a data length of 1 word. The data arrangement information may further contain parameter Leading as being 2, indicating the third data unit is being stored at the start position of the memory segment 1.

The burst access may further wrap the address in the boundary of memory segment. For example, for a burst length of 8 words with a requested address starting from the fifth word, the words would be accessed in the order of 5-6-7-0-1-2-3-4. In some implementations, the memory segment may be accessed in a decreasing address order, wrapping around to the end of a data block when the start is reached. In a case as such, for a burst length of 8 words with a requested column address starting from the fifth word, the words would be accessed in the order of 5-4-3-2-1-0-7-6.

FIGS. 7A and 7B are memory layout diagrams of data access schemes 7A and 7B according to another embodiment of the invention, incorporating the data access system 1 in FIG. 1. The data access schemes 7A and 7B write two data units of regions of a data array into memory segments of the off-chip memory 16 by utilizing predefined memory footprints, and are adopted for data transactions of sequential or random data access, multiple data access, and variable data lengths transmission. Referring to FIG. 7A, illustrating predefined memory footprints in which each data unit is placed successively on one end of a memory segment, offering flexibility of providing random access, multiple access, and variable-length data access. Both data units belonging to one region can be read out in one single transaction since they are logically adjacent to one another in the sequential burst mode. The predefined memory footprint represents start positions of data units of the region, as well as defining a space in the memory segment where the data units of the region are to be written.

For first and second data units that belong to one region of a data array, the first data unit adopts a first memory footprint while the second data unit adopts a second memory footprint in a corresponding memory segment, where the first memory footprint places data units from a start end or a left end toward the center part of the memory segment, and the second memory footprint places data units from a tail end or a right end toward the center part of the memory segment. For example, in the memory segment 1, the first data unit occupies the first two words of the memory segment 1 while the second data unit occupies the last word of the memory segment 1; in the memory segment 2, the first data unit occupies the first three words of the memory segment 2 while the second data unit occupies the last two words of the memory segment 2; in the memory segment 3, the first data unit occupies the first two words of the memory segment 3 while the second data unit occupies the last word of the memory segment 3.

Turning to FIG. 7B, illustrating another predefined memory footprints in which each data unit is placed successively from the center of a memory segment, offering data access for each data unit with flexibility of the random data access, multiple data access, and variable data lengths transmission. Both data units belonging to one region can be read out in one single transaction since they are physically and logically adjacent to one another in the sequential burst mode.

For first and second data units that belong to one region of a data array, the first data unit adopts a first memory footprint while the second data unit adopts a second memory footprint in a corresponding memory segment, where the first memory footprint places data units from the center part toward a start end or a left end of the memory segment, and the second memory footprint places data units from the center part toward a tail end or a right end of the memory segment. For example, in the memory segment 1, the first data unit occupies the two words left from the center of the memory segment 1 while the second data unit occupies the word right from the center of the memory segment 1; in the memory segment 2, the first data unit occupies the three words left from the center of the memory segment 2 while the second data unit occupies the two words right from the center of the memory segment 2; in the memory segment 3, the first data unit occupies the two words left from the center of the memory segment 3 while the second data unit occupies the word right from the center of the memory segment 3.

In some embodiments, the first and second data units are written into the assigned memory segment in a random and separate order. In other embodiments, when both data units are available, the first and second data units are written into the assigned memory segment in a sequential order in one transaction. In yet other embodiments, the first and second data units are read from the assigned memory segment in a sequential order in one transaction. For example, in the memory segment 1 of FIG. 7A, the first and second data units may be written into or read from the memory segment 1 in one transaction in the order of 7-0-1.

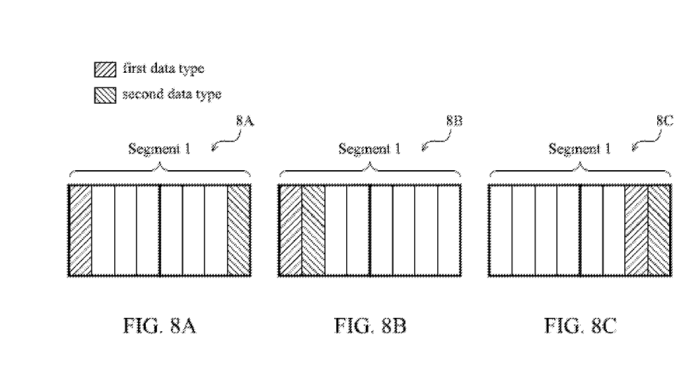

FIGS. 8A, 8B and 8C are memory layout diagrams for a data access scheme 8 according to another embodiment of the invention, incorporating the data access system 1 in FIG. 1. With data access schemes 8, performance can be improved when both data units contain odd numbers of data words.

To be specific, the off-chip memory 16 is, but is not limited to, a type of DDR SDRAM which transfers data on both the rising and falling edges of a clock signal. When a pair of memory word contains only an odd number of data word(s), one of the rising and falling edges will fail to produce a valid data word. The data access performance degrades considerably when significant amounts of odd-number data words are present in the off-chip memory 16 as a consequence of wasting one clock edge for every odd-number data word. This can be illustrated by FIG. 8A, where two data units are arranged in the memory segment 1 according to the data access scheme 7A, and each data unit contains one data word placed in each end of the memory segment 1. As a result, there will be two clock edges wasted in order to access all data units in the memory segment 1.

Therefore, when the data access device determines one of the two data units has already been written into the memory segment 1 and contains an odd number of data words, it can add or append the other data unit to the empty space of the partially occupied memory word pair, as depicted in embodiments in FIGS. 8B and 8C, to enhance data access performance. If the first data unit with a data length of 1-word has been decided to be stored into word 0 of segment 1, the data access device can arrange the second data unit with a data length of 1-word to be stored into word 1 of segment 1, as illustrated in FIG. 8B. On the other hand, if the second data unit with a data length of 1-word has been decided to be stored into word 7 of segment 1, the data access device can arrange the second data unit with a data length of 1-word to be stored into word 6 of segment 1, as shown in FIG. 8C. Auxiliary information such as data arrange information may further be used to distinguish which case is used. In another embodiment, a cache or a data output buffer can be used. The first and the second data units are written into a cache or data output buffer with data arrangement information. These two data units then are written to the off-chip memory 16 due to cache replacement mechanism or output data buffer control mechanism. The data arrangement information can be stored in a local buffer or in the off-chip memory 16.

In the following embodiments, one memory segment can be divided into 2 memory parts. The data unit stored in an upper part of the memory segment is determined to be a first data type, while the data unit stored in a lower part of the memory segment is determined to be a second data type. The data type of a data unit can be identified based on the location information thereof. Once the data type is identified, the manner of determining the start address while writing the data unit can be decided

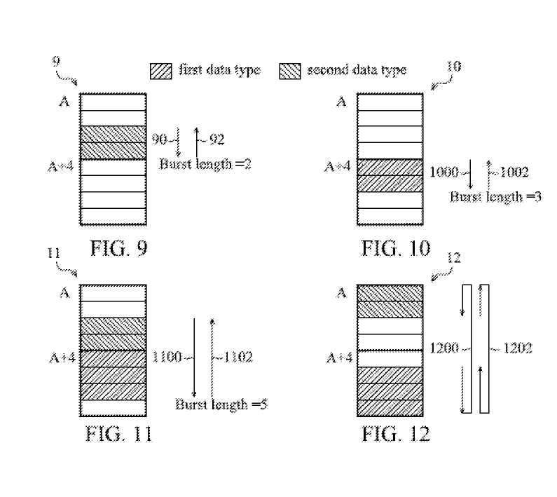

As shown in FIG. 9, assuming that the data units are written from the center toward the start end of the memory segment. The memory segment is divided into 2 memory parts, e.g., an upper part ranging between addresses A and (A+3) and a lower part ranging between addresses (A+4) and (A+7). In FIG. 9, the data unit determined to be the first data type is stored at the addresses (A+2) and (A+3), the data access device can access, which includes reading and writing, the data unit in an incremental address order 90 or a decremental address order 92, with a burst length of 2 data words. The data access device can generate the start address of a burst transfer corresponding to each data unit based on location information of the corresponding data unit. The location information may be index numbers of the data units, index numbers of the memory parts of the memory segment, or starting addresses of the memory parts of the data units are stored therein. For example, for a region contains 2 data units with index numbers T1 and T2, the location information may be T1 or T2. In another example, for a memory segment contains 2 memory parts with index numbers P1 and P2, the location information may be P1 or P2. In the case of the incremental order 90, the data access device can generate the start address by A+(4−DL), where A is a base address of the memory segment, DL is the data length of the data unit, and 4 is the maximal data length of the data unit. The data access device can access the data unit from the addresses (A+2) to (A+3) of the memory segment. In the case of the decremental order 92, the data access device can generate the start address by A+(M−1), with A is the base address of the memory segment, and M is half data length of the memory segment. In the case of FIG. 9, M is four. The data access device can access the data unit from the addresses (A+3) to (A+2) of the memory segment.

In another embodiment as shown in FIG. 10, the data access device may generate a start address for accessing data units from the memory segment. In this embodiment, the data units are written from the center toward the tail end of the memory segment. The memory segment is divided into 2 memory parts, e.g. an upper part ranging between addresses A and (A+3) and an lower part ranging between addresses (A+4) and (A+7). The data unit determined to be the second data type is stored at the addresses (A+4), (A+5) and (A+6). The data access device can access, which includes reading and writing, the data unit in an incremental address order 1000 or an decremental address order 1002, with a burst length of 3 data words. The data access device can generate the start address by (A+4) or (A+M), where A is the base address of the memory segment, and M is half data length of the memory segment (which is four in this embodiment). The data access device can access the second data type from the addresses (A+4) to (A+6) of the memory segment. In the case of the decremental order 1002, the data access device can generate the start address by (A+4)+(DL−1), where A is the base address of the memory segment, and DL is the data length of the second data type. The data access device can access the second data type from the addresses (A+6) to (A+4) of the memory segment.

In FIG. 11, it is assumed that the data unit of the first data type is stored at the addresses (A+2) and (A+3), and the data unit of the second data type is stored at the addresses (A+4), (A+5) and (A+6). The data access device can access all data units in the same region from the addresses (A+2) to (A+6) of the memory segment. To be specific, the burst read may be in a incremental address order 1100 or in a decremental address order 1102, while the burst length is the sum of data lengths of the data units. For the incremental address order 1100, the start address is A+(4−DL1). For the decremental address order 1102, the start address is A+(4+DL2˜1). In which, A is the base address of the memory segment, DL1 is the data length of the data unit of the first data type, DL2 is the data length of the data unit of the second data type, and 4 is the half data length of the memory segment.

In the embodiment shown in FIG. 12, it is assumed that the data unit of the first data type is stored from the addresses A to (A+1), while that the data unit of the second data type is stored from the addresses (A+5) through (A+7). The data access device can access all data units in an incremental wrapping order 1200 or an decremental wrapping order 1202, with a burst length of (DL1+DL2) data words, where DL1 is a data length of the data unit of the first data type, and DL2 is a data length of the data unit of the second data type. For the incremental wrapping order 1200, the start address is A+(4+DL2˜1), and the data access device can access all data units in the same region from the addresses (A+5) to (A+7), wrapping around to the start end, and then from the addresses A to (A+1) of the memory segment. For the decremental wrapping order 1202, the data access device can generate the start address by A+(DL1˜1), and the data access device can access all data units in the same region from the addresses (A+1) to A, wrapping around to the tail end, and then from the addresses (A+7) to (A+5) of the memory segment. In which, A is the base address of the memory segment, and 4 is the half data length of the memory segment.

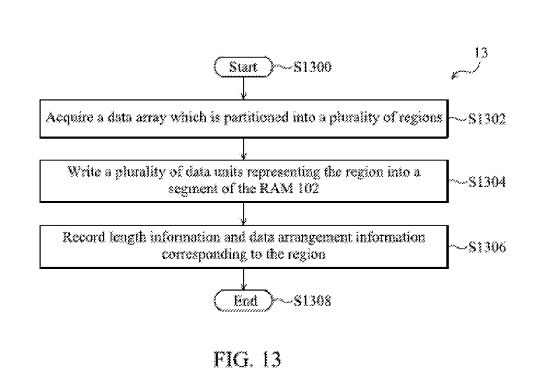

FIG. 13 is a flowchart of a data access method 13 according to an embodiment of the invention, incorporating the data access system 1 in FIG. 1. The data access method 13, writing two or more data units in a region of a data array into a memory segment by utilizing data arrangement information, is adopted for data transactions of sequential or random data access and variable data lengths. The sequential data access may have a predetermined order such as the order of the raster scan. Upon startup, the data access device is initiated for accessing data from the off-chip memory 16 (S1300). The data access device is configured to acquire a data array and partition the data array into a plurality of regions (S1302). The data array may be an image array, a video array, a multimedia array, an executable array, or an application array. Each region may be equal or different in size. The data units may be arranged in a horizontally, vertically, or sequential order as illustrated in FIGS. 3A through 3C. The off-chip memory 16 may be a frame buffer.

The data access device is also configured to access a plurality of memory segments from the off-chip memory 16, wherein each memory segment is allocated for accessing data units of a corresponding region of the data array. For each region, the data units of the region of the data array are then written into the corresponding memory segment in the off-chip memory 16 (S1304), while length information and data arrangement information corresponding to the region are also recorded by the data access device (S1306).

The data units in the same region may be written into the corresponding memory segment by one or more write transactions. After writing all data units of the region to the memory segment, the data access device can read at least two of the data units within the same region at once with a single read transaction based on the length information and the data arrangement information. For example, all of the data units within the same region can be read out by a single read transaction. In other example, each time the data access device performs the data reading operation, only one region is read. In some case, only one data arrangement information is corresponding to one frame.

In some embodiments (e.g., FIG. 5), the data arrangement information indicates which data unit in the region is in the beginning of the corresponding memory segment. In another embodiments (e.g., FIG. 6A/B), the data arrangement information indicates the order or footprint of data units of the same region in the corresponding memory segment. In another embodiments (e.g., FIG. 6A/B), the data arrangement information indicates the start positions of data units of the same region in the corresponding memory segment. In another embodiments (e.g., FIG. 8B/C), the data arrangement information indicates data units of the same region are stored in which end (start or tail end) of the corresponding memory segment. In another embodiment, data arrangement information may include combinational usages of aforementioned embodiments.

In some embodiments, the data units of the same region of the same data array (for example, the same video frame) are randomly written into the memory segment. For example, the data units within the same region of the same data array are written into the memory segment in a first order during a first time period, and are written into the memory segment in a second order during a second time period.

In other embodiments, the data access device may write the data units of a corresponding region of two data arrays into the same memory segment during different time periods, wherein the two data arrays may be two video frames. That is, the data units within a specific region of a first data array are written into the memory device in a first order during a first time period, while the data units within the same specific region of a second data array are written into the memory device in a second order during a second time period. For example, the data units written into the memory device during the first time period are within a region of a first video frame, and the data units written into the memory device during the second time period are within the same region (or co-located region) of a second video frame corresponding to the first video frame. In the foregoing embodiments, each of the first order and the second order may be an unpredictable order, or an order known by the device for writing data and can be identified by the device for reading data according to the data arrangement information.

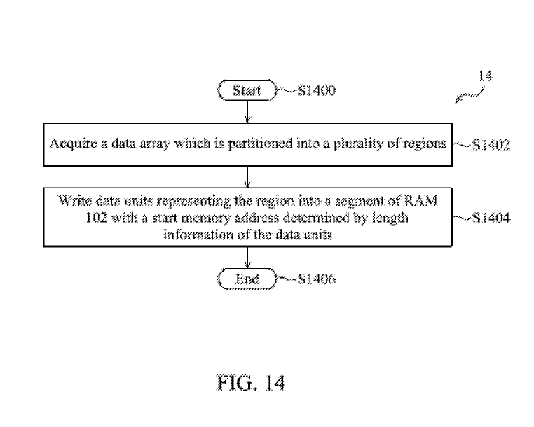

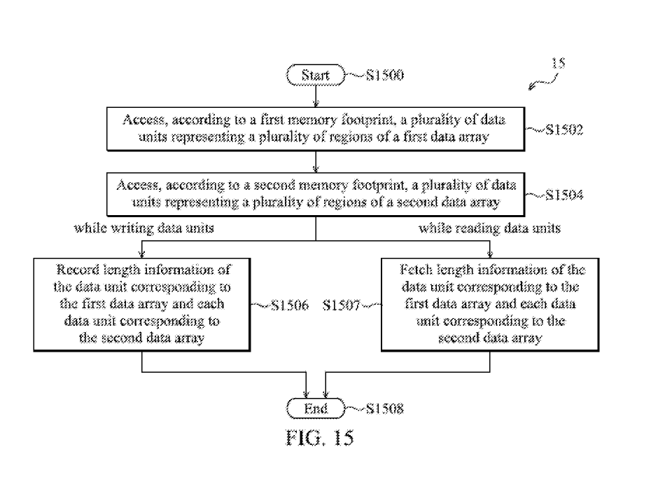

FIG. 14 is a flowchart of an address generation method 14 according to an embodiment of the invention, incorporating the data access system 1 in FIG. 1. Upon startup, the data access device is initiated for accessing data from the off-chip memory 16 (S1400). The data access device is configured to acquire a data array and partition the data array into a plurality of regions (S1402). The data array may be an image array, a video array, a multimedia array, an executable array, or an application array. Each region may be equal or different in size. The data units in the same region may be arranged in a horizontally, vertically, or sequential order as illustrated in FIGS. 3A through 3C. The off-chip memory 16 may be a frame buffer.

The data access device is also configured to allocate a plurality of memory segments from the off-chip memory 16, wherein each memory segment is allocated for accessing data units of a corresponding region of the data array. The data units within the same region of the data array are then written into the corresponding memory segment in the off-chip memory 16 according to a start address determined by length information of the written data (S1404). In one embodiment, the start address of at least one data unit is generated based on the length information thereof. In another embodiment, the start address of every data unit is generated based on the length information thereof. In yet another embodiment, the start address of at least one of the data units is generated without the corresponding length information.

The data units in the same region may be written into the corresponding memory segment by one or more write transactions. After writing all data units of the region into the memory segment, the data access device can read at least two data units within the same region at once with a single read transaction based on the length information of the corresponding data units.

FIG. 15 is a flowchart of a data accessing method 15 according to another embodiment of the invention, incorporating the data access system 1 in FIG. 1. Upon startup, the data access device is initiated for writing data units into the off-chip memory 16 or reading data units from the off-chip memory 16 (S1500). The data access device is configured to acquire first and second data arrays and partition the first and second data arrays into a plurality of regions, respectively. The first and second data arrays may be an image array, a video array, a multimedia data array, or sparse data array, in compressed or uncompressed format. The first and second data arrays may also be program code or instruction code, in compression or un-compression format. Each region may be equal or different in size. The data units in the region may be arranged in a horizontally, vertically, or sequential order as illustrated in FIGS. 3A through 3C. It would be appreciated that the dimension of a region of each of the two data arrays may be different to fit to different processing characteristics and/or different format of data array. For example, each region of the first data array may be the one dimensional region (e.g., the 64×1 region) for ISP engine, while each region of the second data array may be the two dimensional region (e.g., the 8×8 region) for video decoder engine. Besides, the number of data units within a region of a first data array and the number of data units within a region of a second data array may be different. The off-chip memory 16 may be a frame buffer. The data access device is also configured to access a plurality of memory segments from the off-chip memory 16, wherein each memory segment is allocated for the data units of a corresponding region in the first and second data arrays. The first and second data arrays may belong to two video or frame data. The first and second data arrays may have the same or different data formats. For example, the data format may be the bit depth (e.g., the 8, 10, 12 bit-data), or the color component (YUV, RGB, ARGB), etc.

In Step S1502, the data access device performs a first access operation to a plurality of data units representing a plurality of regions of a first data array according to a first memory footprint. In Step S1504, the data access device performs a second access operation to a plurality of data units representing a plurality of regions of a second data array according to a second memory footprint. Each of the first and the second access operations can be a data writing operation or a data reading operation. In one example, the first access operation is to read a first data array and the second access operation is to write data into a second data array. In another example, the first access operation is to read a first and a second data arrays and the second access operation is to write data into the second data array.

The access operation relevant to the data units representing the regions of the first data array and the access operation relevant to the data units representing the regions of the second data array are performed concurrently. Alternatively, these two access operations can be performed at different times.

In some embodiments, the first data array and the second data array are written into the same or different memory segments of the off-chip memory 16 by different data access devices. Alternatively, the first data array and the second data array may be written into different memory devices, such as different frame buffers. On the other hand, the first data array and the second data array are read from the same or different memory segments of the off-chip memory 16 by different data access devices. Or, the first data array and the second data array may be read from different memory devices, such as different frame buffers.

In some embodiments, the first memory footprint and the second memory footprint are respectively determined according to an address range of the first data array and an address range of the second data array. Alternatively, the first memory footprint and the second memory footprint are respectively determined according to a predetermined configuration. For example, a control register of data access device is designed to indicate which kind of memory footprint is used to access a data array. A data access device may have several control registers, each indicates a memory footprint of a data array. In another embodiment, the first memory footprint and the second memory footprint are respectively determined according to the read/write operations. In another embodiment, the first memory footprint and the second memory footprint are respectively determined according to data format of data array.

While the access operation is the data writing operation, the data access device is configured to record length information related to the data unit corresponding to the first data array and the second data array in the off-chip memory 16 (S1506). In some embodiments, the data access device is configured to use a common length cache for writing the data units within the first and second data arrays. It would be appreciated that the data access device is configured to generate the start address for writing the data units of the first and second data arrays by a common address generator circuit. In one embodiment, each data unit corresponding to the first data array and the second data array is compressed before writing into the off-chip memory 16.

While the access operation is the data reading operation, the data access device is configured to fetch, use, or process length information to access the data units of the regions from the memory segments of the off-chip memory 16 (S1507). In a read transaction, the data access device is configured to fetch and use the length information of the store data to compute, calculate, or determine a start address and a burst length for reading the data from the off-chip memory 16. In some embodiments, the data access device is configured to acquire the length information of the data units of the corresponding regions of the first and second data arrays from a common length cache. In other embodiments, the data access device is configured to generate the start address for reading the data units of the first and second data arrays by a common address generator circuit.

The data accessing method 15 allows the data access device to access the data from the off-chip memory 16 multiple times by two predefined memory footprints, thereby allowing the data of the same region to be accessed in one transaction or successive transactions, resulting in an increased data access performance.

In an embodiment, when the access operation is the data writing operation, a first bit range of data unit of the first data array is compressed and a second bit range of data unit of the second data array is compressed. When the access operation is the data reading operation, a first bit range of data unit of the first data array is decompressed and a second bit range of data unit of the second data array is decompressed.

In another embodiment, when the access operation is the data writing operation, a first number of color components of the first data array will be grouped into a first data unit, and the first data unit is compressed. Besides, a second number of color components of the second data array will be grouped into a second data unit, and the second data unit is compressed. Correspondingly, when the access operation is the data reading operation, the first data unit of the first data array is decompressed, and the first number of color components is extracted from the decompressed first data unit. The second data unit of the second data array is decompressed, and the second number of color components is extracted from the decompressed second data unit.

In yet another embodiment, when the access operation is the data writing operation, a first number of color components of the first data array is compressed and a second number of color components of the second data array is compressed. When the access operation is the data reading operation, the first number of color components of the first data array is decompressed and the second number of color components of the second data array is decompressed.

To be specific, the data accessing method 15 is able to process data with multi-format (due to different data sources) by adjusting the manner of performing the data writing and reading operations according to data unit characteristics, such as the write order behavior or the data unit size. It should be noted that the data accessing method 15 can be applied to any data access device which can perform at least one of the data writing operation and the data reading operation. For the data access device which can only perform the data writing operation, step S1507 in FIG. 15 can be omitted. On the other hand, the data access device which can only perform the data reading operation, step S1506 in FIG. 15 can be omitted.

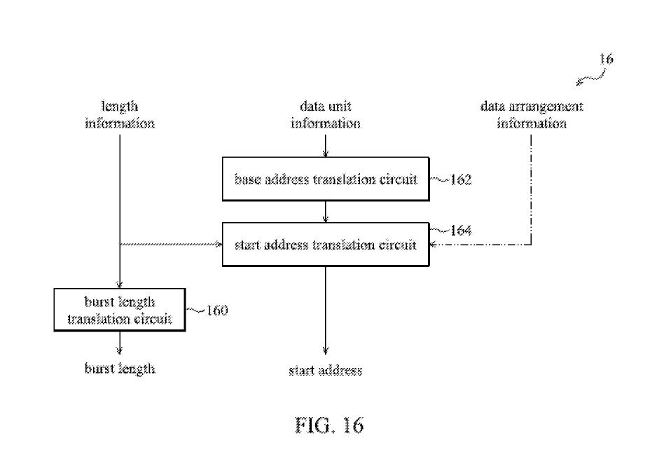

FIG. 16 is a block diagram of an address generation circuit 16 of a write circuit of the data access device according to an embodiment of the invention. The address generation circuit 16 may be incorporated as an address generator AG of a write circuit in the chip 10 in FIG. 1, generating a start address for writing a data array into the off-chip memory 16.

Specifically, the address generation circuit 16 may receive length information, data arrangement information and data unit information and output a start address and a burst length for writing data into the off-chip memory 16. The length information is a length of written data, the data arrangement information may be a writing order and/or a memory footprint, and the data unit information defines an index of a data unit for reading from or writing into the off-chip memory 16. The burst length is a length of a data burst, with a size of a power of two, such as 1, 2, 4, 8, 16 words. In some implementations, the burst length may also be other predetermined lengths of data words. The start address is a memory address of the off-chip memory 16, where the data are written into starting therefrom.

The address generation circuit 16 contains a burst length translation circuit 160, a base address translation circuit 162 and a start address translation 164. The burst length translation circuit 160 may receive the length information to generate a burst length of a write transaction. More specifically, the burst length translation circuit 160 may compute the burst length of a write transaction based on a data size of the written data and an access unit for accessing the off-chip memory 16. That is, the burst length is computed by dividing the compressed/uncompressed data size by the access unit. In one example, the access unit is 16 bytes, the uncompressed data size is 4 words or 64 bytes, and the compressed data size may be, for example, 120 bits or 15 bytes, therefore, the burst length may be computed as 1(=15 bytes/16 bytes, rounded up to the nearest integer). In another example, the compressed data size may be 122 bits or 15.25 bytes, and the burst length may be computed as 1(=15.25 bytes/16 bytes, rounded up to the nearest integer). In yet another example, the compressed data size may be 136 bits or 17 bytes, and the burst length may be computed as 2(=17 bytes/16 bytes, rounded up to the nearest integer).

The base address translation circuit 162 may receive the data unit information to generate a base address for each data unit. The start address translation 164 may generate the start address based on the base address from the base address translation circuit 162 and the data arrangement information. In some implementation, the start address translation 164 may generate the start address by just the base address.

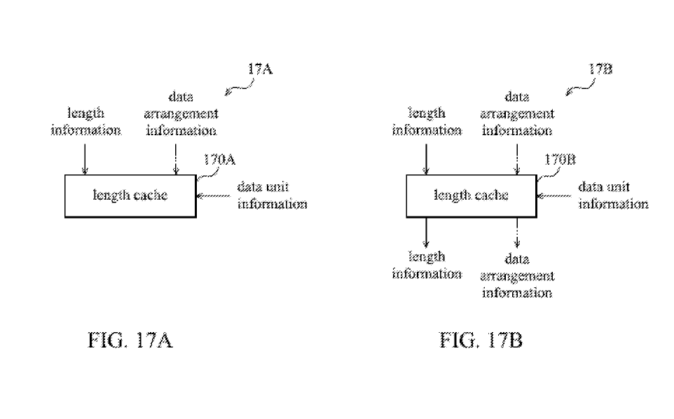

FIGS. 17A and 17B are block diagrams of length caches 170A and 170B of a write circuit of the data access device according to embodiments of the invention. The length cache 170A or 170B may be incorporated as a length cache LC of a write circuit in the chip 10 in FIG. 1, storing length information of data to be written into the off-chip memory 16. When the size of the length cache is insufficient for keeping all the length information, or the length information is used in another device, the length cache 170B may be used. For example, the length information stored in the length cache of the video decoder 104 will be further directed to the display 112. In other cases when the length information is only utilized locally in the data access device, the local length cache 170A may be used. For example, the DSP 114 in FIG. 1 may buffer the length information in the local length cache and does not further pass the length information to another device. The length information may be generated from a device, circuit, or engine other than the data access device. For example, in FIG. 1, the video decoder 104 or GPU 106 may generate the length information, and the display 112 may acquire the length information from the video decoder 104 or GPU 106 to accurately read frame data.

In some of the foregoing embodiments, the data arrangement information corresponding to the first data array and the second data array will be recorded while the data access device is performing a data writing operation.

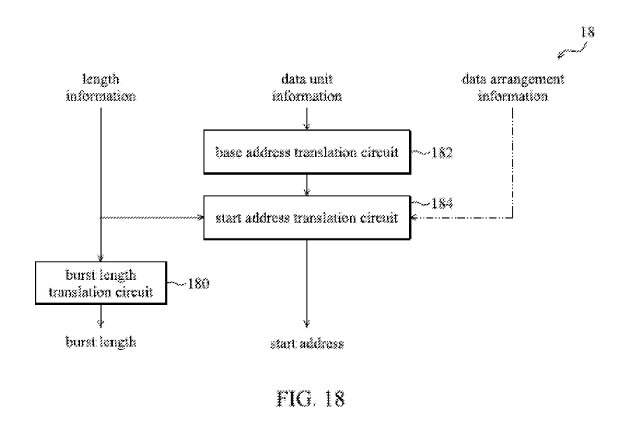

FIG. 18 is a block diagram of an address generation circuit 18 of a read circuit of the data access device according to an embodiment of the invention. The address generation circuit 18 may be incorporated as an address generator AG of a read circuit in the chip 10 in FIG. 1, generating a start address for reading data from the off-chip memory 16.

The address generation circuit 18 contains a burst length translation circuit 180, a base address translation circuit 182 and a start address translation 184. The burst length translation circuit 180 may receive the length information to generate a burst length of a read transaction. More specifically, the burst length translation circuit 180 may compute the burst length of a read transaction based on a data size of the read data and an access unit for accessing the on-chip memory 108 or the off-chip memory 18. That is, the burst length is computed by dividing the compressed/uncompressed data size by the access unit. The base address translation circuit 182 may receive the data unit information to generate a base address for each data unit. The start address translation 184 may generate the start address based on the base address from the base address translation circuit 182 and the data arrangement information. In some implementation, the start address translation 184 may generate the start address by just the base address.

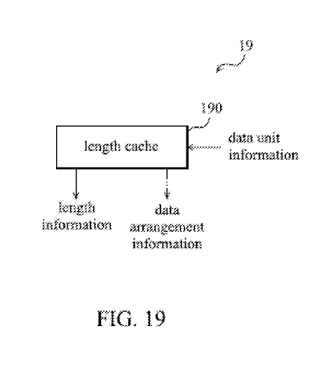

FIG. 19 is a block diagram of length cache 19 of a read circuit of the data access device according to embodiments of the invention. The length cache 19 may be incorporated as an length cache LC of a read circuit in the chip 10 in FIG. 1, storing length information of data to be read from the off-chip memory 16.

When the number of data units is large, the size of all length information for the data units may also be too large such that not all length information can be loaded into a local buffer such as the length caches 17A, 17B, or 19. In this condition, only length information of a part of data units are loaded into the local buffer. When the access order is fixed or known to the data access device, the data refresh of the local buffer can be pre-scheduled. Otherwise, a cache replacement policy may be defined in order to provide the best performance for a particular application. People skilled in the art may recognize that cache replacement policies have already been developed and may be applied to the present application. The local buffer may have a pre-scheduled replacement mechanism or pre-fetch mechanism to load length information stored in mass storage (e.g., the off-chip memory 16). Furthermore, all length information may still be stored in the local buffer whenever necessary.

It is possible to read length information of two or more data units at a time. For example, in order to read compressed data unit (1,1) and data unit (1,2) in single read transaction, the length information of the data unit (1,1) (with a data size of 2 words) and the data unit (1,2) (with a data size of 3 words) will be acquired to compute a burst length of 5 words(=2 words+3 words).

In the read circuit, before reading compressed data from the off-chip memory 16, the data arrangement information along with the length information are loaded into the same local buffer. Alternatively, a separate local buffer for storing data arrangement information is implemented. The replacement policy of data arrangement information can be identical to that of length information. The size of data arrangement information may be much less than that of length information.

When length and data arrangement information are generated by a first processing engine, such as the GPU 106 or the ISP 110 in FIG. 1, and are required by a second processing engine, such as the display 112 and the monitor 14 in FIG. 1, these two types of information will be delivered from the first processing engine to the second processing engine. The information delivery could be, for example, through DRAM.

Specifically, the first processing engine (hereinafter referred to as a data generator) may generate compressed data, and the second processing engine (hereinafter referred to as data consumer) may read the compressed data and perform signal processing thereon. In some embodiments, a single processing engine such as a CPU 100 may behavior as the data generator and the data consumer.

In the write circuit, the length cache may receive the data arrangement information for two usages. The first usage is for storing the data arrangement information together with the length information. The second usage is for outputting the data arrangement information of a particular region first.

In one example, two data units P and Q may be accessed from one cohabitation segment in memory. If the read data arrangement information indicates no data unit have been written into this cohabitation segment (e.g., leading bit=0), the data agent DA in the data access device may generate a write address of the data unit P, update the data arrangement information of this cohabitation segment by, for example, setting the leading bit to 1, and storing a data length DLp of data unit P into the corresponding length cache. Conversely, if the read data arrangement information indicates there is a data unit Q which has been written into this cohabitation segment (e.g., leading bit=1), the data agent DA in the data access device may generate a write address of this data unit P, update the data arrangement information of this cohabitation segment by, for example, leaving the leading bit as 1, and store the data length DLp of the data unit P into the corresponding length cache. Alternatively, the total length of the data units P and Q may be saved.

In some embodiments, the length information of each data unit corresponding to the first data array and the second data array is fetched, the valid data of each data unit corresponding to the first data array and the second data array is indicated by the fetched length information of the corresponding data unit, and the data arrangement information corresponding to each region of the first data array and the second data array is fetched so as to read out each data unit corresponding to the first data array and the second data array.

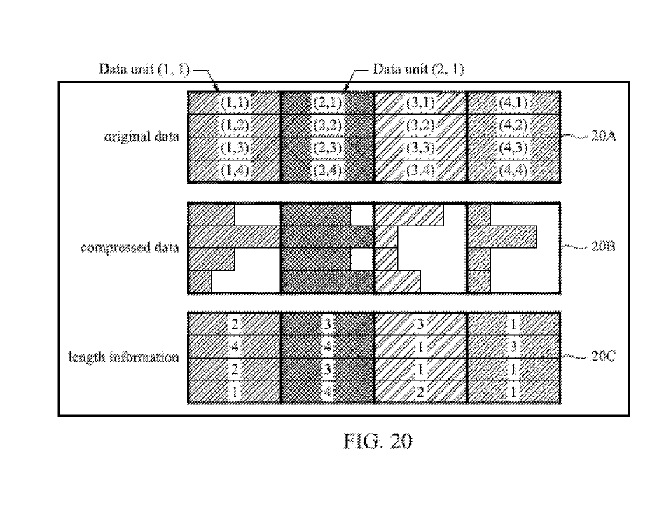

Please refer to FIG. 20, showing a data array of uncompressed data, compressed data, and length information thereof respectively. In an example where the leading bit or the memory footprint is implemented, the display system may need to process frames generated by the ISP 110, the GPU 106 and the video decoder 104 in FIG. 1. In this example, RGB is used by ISP as the frame format. Herein, The data array in the FIG. 20A contains a plurality of data units representing predefined regions, and each data unit is, for example, 1-D 64×1 color component block (e.g., R, G, or B color component, a pixel contains R, G, B color components). The compressed data have been already aligned to data grids of 16, 32, 48, 64 bytes, as indicated in the compressed data table in FIG. 20B, and the length information table for each data unit is provided in FIG. 20C. The number in the length information is corresponding to the compressed data size, aligned to DRAM word size. The compressed data size of a data unit (1, 1) is, for example, 140 bits (17.5 bytes), and will occupy 2 DRAM words, and the compressed data size of a data unit (2, 1) is, for example, 3 DRAM words, wherein each DRAM word has a size of 16 bytes.

In another example, a data access operation with the memory footprint and without the leading bit information is implemented as shown in FIG. 7B. The memory footprint may be one of the following, with base addresses of the memory being indexed by hexadecimal numbers incremented every ‘h0004. For example, the base addresses may be ‘h0000, ‘h0004, ‘h0008, ‘h000C, ‘h1000, and so on.

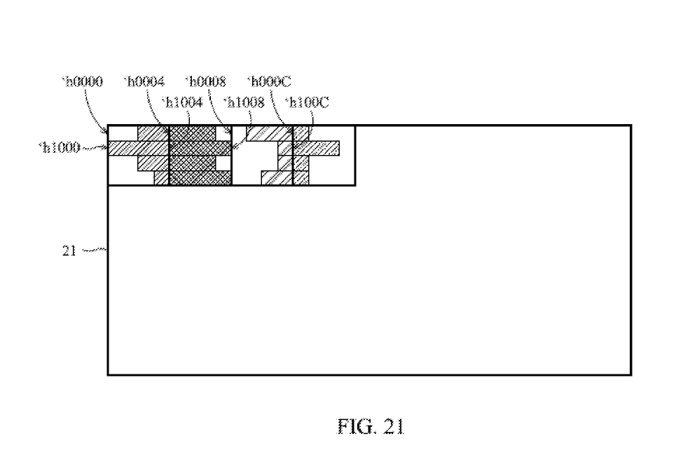

Based on this implementation, the memory footprint of compressed data of FIG. 20A would be FIG. 21 and some access examples may be:

writing the compressed data unit (1,1) with a start address at ‘h0002 and a burst length of 2 words;
writing the compressed data unit (2,1) with a start address at ‘h0004 and a burst length of 3 words;
reading the compressed data unit (1,1) with a start address at ‘h0002 and a burst length of 2 words;
reading the compressed data unit (1,1) and data unit (2,1) in a single read transaction, with a start address at ‘h0000 and a burst length of 7 words(=4 words+3 words); or
writing the compressed data unit (1,1) and data unit (2,1) in a single write transaction, with a start address at ‘h0000 and a burst length of 7 words(=4 words+3 words).

If the output local buffer is large enough, all data units in the same region may be written out in a single write transaction by a suitable burst length setting. In some embodiments, when the size of the data units to be transmitted is large, the data transaction may be broken into two or more data bursts. For example, if the size of the data units to be transmitted is 12 words, due to the maximal burst length is 8 words in length in the exemplary DRAM protocol, the data transaction may be broken into an 8-word data burst and a 4-word data burst.

Referring now to FIG. 21, which shows a memory layout diagram 21 illustrating a data access scheme according to an embodiment of the invention. The horizontally adjacent data units in the same region are stored in continuous memory space. In particularly, the data units horizontally adjacent to one another are denoted by different shadow patterns in FIG. 21.

In one example as shown in FIG. 21, the start address for accessing the compressed data unit (1,1) in the incremental address order is obtained by:

Base address+(M−length)=‘h0000+(‘h4−‘h2)=‘h0002, where M=4.

Alternative, the start address for acceding data unit (1,1) in the decremental address order may be:

Base address+(M−1)=‘h0000+(‘h4−‘h1)=‘h0003.

In another example as shown in FIG. 10, the start address for accessing the compressed data unit (2,1) in the incremental address order is obtained by:

calculating Base address+(4)=‘h0000+(‘h4)=‘h0004; or
calculating Base address+(M)=‘h0000+(‘h4)=‘h0004; or
defining the base address for group (2,1) is ‘h0004 in a look-up table.

In some implementations, the address translation circuit 162 in FIG. 16 and address translation circuit 182 in FIG. 18 may include a look-up table, and may or may not include an adder.

Alternative, the start address for accessing the data unit (2,1) in the decremental address order may be:

Base address+4+(length−1)=Base address+3+length=‘h0000+‘h3+‘h3=‘h0006; or
Base address+length=‘h0003+‘h3=‘h0006.

In the foregoing example, the base address may be ‘h0000 or ‘h0003.

By storing the horizontally adjacent data units in the same region into a continuous memory space, a size of the data buffer for accessing the data units may be reduced, in particularly when the data units are accessed or processed in a raster scan order.

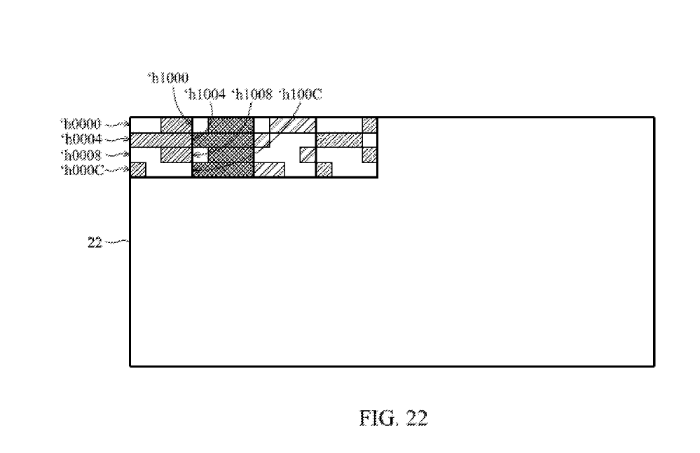

Referring now to FIG. 22, which shows a memory layout diagram 22 illustrating a data access scheme according to an embodiment of the invention. The vertically adjacent data units in the same region are stored in continuous memory space. In particularly, the data units vertically adjacent to one another are denoted by the same shadow patterns in FIG. 22.

In FIG. 22, the memory footprint for a write operation may be one of the following:

writing the compressed data unit (1,1) with a start address at ‘h0002 and a burst length of 2 words;
writing the compressed data unit (1,2) with a start address at ‘h0004 and a burst length of 4 words;
reading the compressed data unit (1,1) with a start address at ‘h0002 and a burst length of 2 words;
reading the compressed data unit (1,1) and data unit (1,2) in a single read transaction with a start address at ‘h0002 and a burst length of 6 words(=2 words+4 words); and
writing the compressed data unit (1,1) and data unit (1,2) in a single write transaction with a start address at ‘h0002 and a burst length of 6 words(=2 words+4 words).

That is, the start address of writing compressed data unit (1,1) is the same as in previous descriptions.

In FIG. 22, the start address for accessing the compressed data unit (1,2) in the incremental address order is obtained by:

calculating Base address+(4)=‘h0000+(‘h4)=‘h0004; or
calculating Base address+(M)=‘h0000+(‘h4)=‘h0004; or
defining the base address for group (1,2) is ‘h0004 in a look-up table.

Alternative, the start address for accessing the data unit (1,2) in the decremental address order may be:

Base address+4+(length−1)=Base address+3+length=‘h0000+‘h3+‘h4=‘h0007; or
Base address+length=‘h0003+‘h4=‘h0007.

By storing the vertically adjacent data units in the same region into a continuous memory space, a size of the data buffer for accessing the data units may be reduced, in particularly when the data units are accessed or processed in a vertical scan order.

In some embodiments, the data access may be performed with different group sizes in different conditions. In one implementation, a memory entry is 128-bit DRAM word in length, and a color component (such as R of RGB or Y of YUV) may be represented by 8-bit, 10-bit, 12-bit data. A data unit having a size of 64 components (e.g., 64 units of Y) may be represented by a 64×1 data array in 1 dimension or a 8×8 data array in 2 dimension. In the case of 8-bit color components, the original data size of a group is 64×8 (bits)=4×128 (bits) and can be stored in 4 memory entries. Similarly, In the case of 10-bit and 12-bit color components, the original data size of a group is 5×128 and 6×128 bits respectively. If a 8-bit color component is supported, the length information can be represented by 2 bits for representing a compressed data unit having a size of 1, 2, 3, or 4 DRAM words. The length information indicating 4 may indicate that the uncompressed data unit is stored. If 10-bit or even 12-bit color components are supported, the length information may be represented by 3 bits for a compressed data unit having a data size of 1, 2, 3, 4, 5, or 6 DRAM words.

Alternative design is to keep 2-bit length information with a different representation. Take 10-bit color component as an example. 2 bits of a 10-bit data may be kept uncompressed. Then 64 components would require 128 bits(=64×2 bits) uncompressed data, which in turn lead to at least one 128-bit DRAM word is required for these uncompressed bits. A value of 1 stored in the length cache indicates the data length of corresponding data unit is 2. Similarly, a value of 2, 3, or 4 stored in length cache indicates the data length of corresponding data unit is 3, 4, or 5 respectively. Please refer the following table for a summary of aforementioned conditions:

TABLE 1

| Value stored in | 8-bit color | 10-bit color | 12-bit color |
|---|---|---|---|
| the length cache | component | component | component |
| 1 | 1 | 2 | 3 |
| 2 | 2 | 3 | 4 |
| 3 | 3 | 4 | 5 |
| 4 | 4 | 5 | 6 |

The burst length translation circuits in FIGS. 16 and 18 need to generate correct burst length according to the type of component (e.g., 8, 10, 12 bits). In some of the embodiments, the exact values stored in the length cache may further be represented in different numbering format. For example, 2-bit 2′b00, 2′01, 2′b10, 2′b11 may be used to represent the value 1, 2, 3, 4 respectively for further reducing the cost of storing these values for length information.

In another embodiment, different data unit sizes may be supported for different applications. Take YUV420 frames as the example, a data unit has a size of 64 components for Y plane while has a size of 16 components for U plane. The original size of a data unit for U is 16 bytes when 8-bit color component is adopted. Alternatively, a data unit has a size of 64 components for U plane can be adopted. In this case, the total number of data unit for U plane would be ¼ of that for Y plane. The burst length and start address generation then be adjusted accordingly when supporting different format.

In another embodiment, two color components are compressed individually and the compressed data are packed as a single data unit. For example, 32 components of a region of U plane are compressed and 32 components of a co-located region of V plane are compressed. The data length of the same region of U and V then can still be represented as 1˜4.

In another embodiment, two color components may be packed first and then be compressed. For example, 32 components of a region of U plane and 32 components of a co-located region of V plane are packed and compressed. The data length of the same region of U and V then can still be represented as 1˜4.

In some applications, different number of color component is represented for a pixel, e.g., RGB 3 color components or ARGB 4 color components. Each color component plane can be partitioned into a plurality of regions; and each region has a plurality of data units. Data units of different color components are compressed separately. Then the address generation, burst length generation, length cache, and data arrangement information (if any) are required to handle different color components separately.

In another embodiment, two or more color components may be packed first and then partitioned into a plurality of regions; and each region has a plurality of data units. In this case, each data unit has more than one color components. Then the address generation, burst length generation, length cache, and data arrangement information (if any) are required to handle different data partition methods.

In another embodiment, two or more color components may be compressed first and then packed as a single data unit. In this case, each data unit has more than one color components. Then the address generation, burst length generation, length cache, and data arrangement information (if any) are required to handle different data partition methods.

As used herein, the term “determining” encompasses calculating, computing, processing, deriving, investigating, looking up (e.g., looking up in a table, a database, or another data structure), ascertaining, and the like. Also, “determining” may include resolving, selecting, choosing, establishing, and the like.

The various illustrative logical blocks, modules and circuits described in connection with the present disclosure may be implemented or performed with a general purpose processor, a digital signal processor (DSP), an application-specific integrated circuit (ASIC), a field programmable gate array signal (FPGA) or another programmable logic device, discrete gate or transistor logic, discrete hardware components, or any combination thereof designed to perform the functions described herein. A general-purpose processor may be a microprocessor, but in the alternative, the processor may be any commercially available processor, controller, microcontroller, or state machine.

The operations and functions of the various logical blocks, units, modules, circuits and systems described herein may be implemented by way of, but not limited to, hardware, firmware, software, software in execution, and combinations thereof.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A data access method, comprising:
acquiring a data array which is partitioned into a plurality of regions; and
for each of the regions, writing a plurality of data units representing the region into a segment of a memory device and recording both of length information and data arrangement information corresponding to the region, wherein a burst length of a burst access performed on the data units representing the region is defined according to the length information.

2. The method according to claim 1, wherein the data arrangement information indicates at least one of a write order and a memory footprint of the data units within a same region of the data array.

3. The method according to claim 1, wherein the data units within a same region of the same data array are written into the memory device in a first order during a first time period, and are written into the memory device in a second order during a second time period.

4. The method according to claim 1, wherein the data units within a specific region of the data array are written into the memory device in a first order during a first time period, while a plurality of data units within the same specific region of another data array are written into the memory device in a second order during a second time period.

5. The method according to claim 1, wherein at least two of the data units written into a same segment of the memory device are read out by a single read transaction.

6. The method according to claim 1, wherein the data units within a same region are horizontally adjacent to each other.

7. The method according to claim 1, wherein the data units within a same region are vertically adjacent to each other.

8. The method according to claim 1, further comprising:
starting from a base address of the segment, writing the data units within a same region into the segment in accordance with a write order of the data units.

9. A data access method, comprising:
acquiring a data array which is partitioned into a plurality of regions; and
for each of the regions, writing a plurality of data units representing the region into a segment of a memory device, wherein a start address of a write transaction for at least one of the data units is generated based on length information of the corresponding data unit.

10. The method according to claim 9, wherein the start address of the write transaction for at least another one of the data units is generated without the corresponding length information.

11. The method according to claim 9, wherein the start address of the write transaction corresponding to each of the data units is further generated based on location information of the corresponding data unit.

12. The method according to claim 9, wherein the data units within a same region of the same data array are written into the memory device in a first order during a first time period, and are written into the memory device in a second order during a second time period.

13. The method according to claim 9, wherein the data units within a specific region of the data array are written into the memory device in a first order during a first time period, while a plurality of data units within the same specific region of another data array are written into the memory device in a second order during a second time period.

14. The method according to claim 9, wherein at least two of the data units written into a same segment of the memory device are read out by a single read transaction.

15. The method according to claim 9, wherein the data units within a same region are horizontally adjacent to each other.

16. The method according to claim 9, wherein the data units within a same region are vertically adjacent to each other.

17. A method of accessing data in a data processing system with a memory device, the method comprising:
performing an access operation on the memory device by accessing, according to a first memory footprint, a plurality of data units representing a plurality of regions of a first data array;
performing the access operation on the memory device by accessing, according to a second memory footprint, a plurality of data units representing a plurality of regions of a second data array; and
performing the access operation according to the length information of data units.

18. The method according to claim 17, wherein the access operation is a data writing operation, the method further comprises:
compressing each data unit corresponding to the first data array and the second data array before writing into the memory device.

19. The method according to claim 17, wherein the access operation is a data writing operation, the method further comprises:
recording data arrangement information corresponding to the first data array and the second data array.

20. The method according to claim 17, wherein the access operation is a data writing operation, the method further comprises:
compressing a first bit range of data unit of the first data array; and
compressing a second bit range of data unit of the second data array.

21. The method according to claim 17, wherein the access operation is a data reading operation, the method further comprises:
decompressing a first bit range of data unit of the first data array; and
decompressing a second bit range of data unit of the second data array.

22. The method according to claim 17, wherein the access operation is a data writing operation, the method further comprises:
grouping a first number of color components of the first data array into a first data unit;
compressing said first data unit;
grouping a second number of color components of the second data array into a second data unit; and
compressing said second data unit.

23. The method according to claim 17, wherein the access operation is a data reading operation, the method further comprises:
decompressing a first data unit of the first data array;
extracting a first number of color components from decompressed first data unit;
decompressing a second data unit of the second data array; and
extracting a second number of color components from decompressed second data unit.

24. The method according to claim 17, wherein the access operation is a data writing operation, the method further comprises:
compressing a first number of color components of the first data array; and
compressing a second number of color components of the second data array.

25. The method according to claim 17, wherein the access operation is a data reading operation, the method further comprises:
decompressing a first number of color components of the first data array; and
decompressing a second number of color components of the second data array.

26. The method according to claim 17, wherein the access operation is a data reading operation, the method further comprises:
processing the length information by fetching the length information of each data unit corresponding to the first data array and the second data array;
indicating valid data of each data unit corresponding to the first data array and the second data array by the fetched length information of the corresponding data unit; and
fetching data arrangement information corresponding to each region of the first data array and the second data array so as to read out each data unit corresponding to the first data array and the second data array.

27. The method according to claim 17, wherein the first memory footprint and the second memory footprint are respectively determined according to a predetermined configuration.

28. The method according to claim 17, wherein the first memory footprint and the second memory footprint are respectively determined according to an address range of the first data array and an address range of the second data array.

29. The method according to claim 17, further comprising:
accessing the data units within the first data array according to the first memory footprint and the data units within the second data array according to the second memory footprint by using a common address generation circuit.

30. The method according to claim 17, further comprising:
accessing the data units within the first data array according to the first memory footprint and the data units within the second data array according to the second memory footprint by using a common length cache.
